(19) United States
(12) Patent Application Publication
(10) Pub. No.: US 2024/0347601 A1
(43) Pub. Date: Oct. 17, 2024

(54) COMPOSITE SUBSTRATES, SEMICONDUCTOR STRUCTURES, AND METHODS FOR MANUFACTURING COMPOSITE SUBSTRATES

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/634,480

(22) Filed: Apr. 12, 2024

(30) Foreign Application Priority Data
Apr. 17, 2023 (CN) 202310411773.8

(51) Int. Cl. H01L 29/16; H01L 21/02; H01L 29/04

(52) U.S. Cl. CPC H01L 29/1608; H01L 21/02447; H01L 21/02529; H01L 21/02598; H01L 29/04

(57) ABSTRACT

The present disclosure provides a composite substrate including: a support layer; and a SiC monocrystalline layer on the support layer, where the SiC monocrystalline layer includes a first superjunction structure that includes first P-type layers and first N-type layers, and the first P-type layers and the first N-type layers extend inward along a thickness direction of the SiC monocrystalline layer from a surface of the SiC monocrystalline layer far from the support layer, and are alternately distributed in a direction parallel to a plane of the SiC monocrystalline layer.

### CROSS REFERENCE TO RELATED APPLICATIONS

This application claims priority to Chinese Patent Application No. 2023104117738 filed on Apr. 17, 2023, the entire content of which is incorporated herein by reference.

### TECHNICAL FIELD

The present disclosure relates to the technical field of semiconductor, in particular to composite substrates, semiconductor structures, and methods for manufacturing composite substrates.

### BACKGROUND

Wide-bandgap semiconductor material, such as GaN-based material, as a representative third-generation semiconductor material, has excellent properties of wide band gap, high pressure resistance, high temperature resistance, high electron saturation velocity, high drift velocity and easy formation for a high-quality heterostructure, which is suitable for manufacturing a high temperature, high frequency and high-power electronic device.

Because lattice constants of SiC and GaN materials are similar, a GaN-based material grown on a SiC monocrystalline material have fewer defects and better properties. However, the cost of the SiC monocrystalline material is relatively high, and using the SiC monocrystalline material as semiconductor substrates requires more or larger SiC monocrystalline materials, resulting in higher costs.

Therefore, it is necessary to provide a SiC composite substrate.

### SUMMARY

In the first aspect, a composite substrate is provided in the present disclosure, and includes: a support layer; and a SiC monocrystalline layer on the support layer, where the SiC monocrystalline layer includes a first superjunction structure that includes first P-type layers and first N-type layers, and the first P-type layers and the first N-type layers extend inward along a thickness direction of the SiC monocrystalline layer from a surface of the SiC monocrystalline layer far from the support layer, and are alternately distributed in a direction parallel to a plane of the SiC monocrystalline layer.

In some embodiments, the composite substrate further includes: a SiC epitaxial layer on a side of the SiC monocrystalline layer far from the support layer.

In some embodiments, the SiC epitaxial layer includes a second superjunction structure that includes second P-type layers and second N-type layers, and the second P-type layers and the second N-type layers extend inward along a thickness direction of the SiC epitaxial layer from a surface of the SiC epitaxial layer far from the SiC monocrystalline layer, and are alternately distributed in a direction parallel to a plane of the SiC epitaxial layer.

In some embodiments, along the thickness direction of the SiC monocrystalline layer, the first P-type layers are connected to the second P-type layers, and the first N-type layers are connected to the second N-type layers.

In some embodiments, along the thickness direction of the SiC monocrystalline layer, the first P-type layers are connected to the second N-type layers, and the first N-type layers are connected to the second P-type layers.

In some embodiments, the composite substrate further includes: a buried oxide layer between the support layer and the SiC monocrystalline layer.

In some embodiments, the support layer includes holes on a side close to the SiC monocrystalline layer, the holes partially penetrate the support layer, and the buried oxide layer fills the holes and covers a surface of the support layer close to the SiC monocrystalline layer.

In some embodiments, the holes are arranged in an array arrangement or a staggered arrangement.

In some embodiments, a material of the support layer includes a polycrystalline material, and a material of the support layer includes at least one of aluminum nitride ceramic substrate, aluminum oxide ceramic substrate, silicon carbide ceramic substrate, boron nitride ceramic substrate, zirconia ceramic substrate, magnesium oxide ceramic substrate, silicon nitride ceramic substrate, beryllium oxide ceramic substrate or polycrystalline silicon.

In the second aspect, a semiconductor structure is further provided in the present disclosure, and includes: the composite substrate according to any one of the above embodiments, and one of a high-electron-mobility transistor device, a vertical power device, a radio frequency device and a light-emitting diode device.

In the third aspect, a method for manufacturing a composite substrate is further provided in the present disclosure, and includes: providing a support layer; forming a Si monocrystalline layer on the support layer; forming a first superjunction structure by implanting ions into the Si monocrystalline layer, where the first superjunction structure includes first P-type layers and first N-type layers, and the first P-type layers and the first N-type layers extend inward along a thickness direction of the Si monocrystalline layer from a surface of the Si monocrystalline layer far from the support layer, and are alternately distributed in a direction parallel to a plane of the Si monocrystalline layer; and after forming the first superjunction structure, obtaining a SiC monocrystalline layer by carbonizing the Si monocrystalline layer.

In some embodiments, after obtaining the SiC monocrystalline layer, the method further includes: forming a SiC epitaxial layer on a side of the SiC monocrystalline layer far from the support layer.

In some embodiments, after forming the SiC epitaxial layer on the side of the SiC monocrystalline layer far from the support layer, the method further includes: forming a second superjunction structure by implanting ions into the SiC epitaxial layer, where the second superjunction structure includes second P-type layers and second N-type layers, and the second P-type layers and the second N-type layers extend inward along a thickness direction of the SiC epitaxial layer from a surface of the SiC epitaxial layer far from the SiC monocrystalline layer, and are alternately distributed in a direction parallel to a plane of the SiC epitaxial layer.

In some embodiments, along the thickness direction of the SiC monocrystalline layer, the first P-type layers are connected to the second P-type layers, and the first N-type layers are connected to the second N-type layers.

In some embodiments, along the thickness direction of the SiC monocrystalline layer, the first P-type layers are connected to the second N-type layers, and the first N-type layers are connected to the second P-type layers.

In some embodiments, forming the Si monocrystalline layer on the support layer includes: forming a buried oxide layer on the support layer; and forming the Si monocrystalline layer on a side of the buried oxide layer far from the support layer.

In some embodiments, forming the buried oxide layer on the support layer includes: forming holes on the support layer, where the holes partially penetrate the support layer; and forming the buried oxide layer on the support layer, where the buried oxide layer fills the holes and covers a surface of the support layer on which the holes are located.

In some embodiments, the holes are arranged in an array arrangement or a staggered arrangement.

### BRIEF DESCRIPTION OF DRAWINGS

FIG. 1 is a schematic structural diagram of a composite substrate according to embodiments of the present disclosure.

FIG. 2 is a schematic structural diagram of a composite substrate according to embodiments of the present disclosure.

FIG. 3 is a schematic structural diagram of a composite substrate according to embodiments of the present disclosure.

FIG. 4 is a schematic structural diagram of a composite substrate according to embodiments of the present disclosure.

FIG. 5 is a schematic structural diagram of a composite substrate according to embodiments of the present disclosure.

FIG. 6 is a top view of a support layer of a composite substrate according to embodiments of the present disclosure.

FIG. 7 is a top view of a support layer of a composite substrate according to embodiments of the present disclosure.

### DETAILED DESCRIPTION

Exemplary embodiments will be described in detail herein, examples of which are illustrated in the accompanying drawings. Where the following description refers to the drawings, the same numerals in different drawings refer to the same or similar elements unless otherwise indicated. Embodiments described in the illustrative examples below are not intended to represent all embodiments consistent with the present disclosure. Rather, they are merely embodiments of devices and methods consistent with some aspects of the present disclosure as recited in the appended claims.

The term used in the present disclosure is for the purpose of describing particular embodiments only and is not intended to limit the present disclosure. As used in the present disclosure and the appended claims, the singular forms “a”, “an” and “the” are intended to include the plural forms as well, unless the context clearly indicates otherwise. It should further be understood that the term “and/or” as used herein refers to and includes any and all possible combinations of one or more of the associated listed items.

It shall be understood that, although the terms “first,” “second,” “third,” and the like may be used herein to describe various entities, the entities should not be limited by these terms. These terms are only used to distinguish one category of entities from another. For example, without departing from the scope of the present disclosure, a first P-type layer can also be called a second P-type layer, similarly, a second P-type layer can also be called a first P-type layer.

In the present disclosure a composite substrate is provided, which achieves the growth of GaN-based epitaxial material on the SiC monocrystalline material, with relatively small size of the SiC monocrystalline material, thereby reducing costs. In addition, in the present disclosure, the stability of the composite substrate is further enhanced through a superjunction structure.

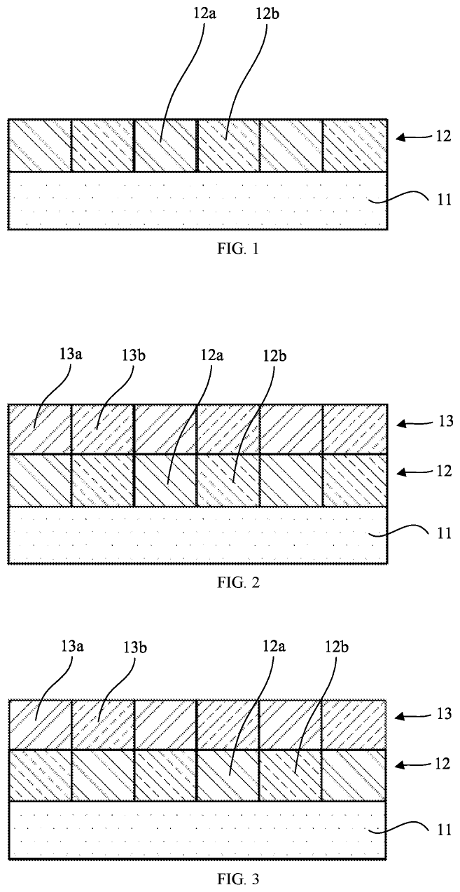

FIG. 1 is a schematic structural diagram of a composite substrate according to embodiments of the present disclosure. As shown in FIG. 1, in the present disclosure, a composite substrate is provided, and includes: a support layer 11; and a SiC monocrystalline layer 12 on the support layer 11, where the monocrystalline layer 12 includes a first superjunction structure, which includes first P-type layers 12a and first N-type layers 12b. The first P-type layers 12a and the first N-type layers 12b extend inward along a thickness direction of the SiC monocrystalline layer 12 from a surface of the SiC monocrystalline layer 12 far from the support layer 11 and are alternately distributed in a direction parallel to a plane of the SiC monocrystalline layer 12.

The first P-type layers 12a and the first N-type layers 12b extend inward along the thickness direction of the SiC monocrystalline layer 12 from the surface of the SiC monocrystalline layer 12 far from the support layer 11, that is, the first P-type layers 12a and the first N-type layers 12b are both located within the SiC monocrystalline layer 12 and the thicknesses of the first P-type layers 12a and the first N-type layers 12b are less than or equal to the thickness of the SiC monocrystalline layer 12. For example, the thickness of the first P-type layer 12a and the thickness of the first N-type layer 12b are both equal to the thickness of the SiC monocrystalline layer 12, and for another example, the thickness of the first P-type layer 12a and the thickness of the first N-type layer 12b both are less than the thickness of the SiC monocrystalline layer 12.

A material of the support layer 11 can include a polycrystalline material, and in some embodiments, a material of the support layer 11 includes at least one of aluminum nitride ceramic substrate, aluminum oxide ceramic substrate, silicon carbide ceramic substrate, boron nitride ceramic substrate, zirconia ceramic substrate, magnesium oxide ceramic substrate, silicon nitride ceramic substrate, beryllium oxide ceramic substrate or polycrystalline silicon. The support layer 11 can provide stress compensation for the structure on the support layer 11, to prevent structural warping and improve structural stability.

Because lattice constants of SiC and GaN materials are similar, a GaN-based material grown on a SiC monocrystalline material have fewer defects and better properties. However, the cost of SiC monocrystalline materials is relatively high. The present disclosure adopts a scheme that combines a support layer and a SiC monocrystalline layer, which can effectively reduce the thickness of the SiC monocrystalline layer and thereby reduce costs. In addition, in the present disclosure, a first superjunction structure is further provided to enhance the resistivity and stability of the SiC monocrystalline layer. The first superjunction structure has multiple PN junctions composed of first P-type layers 12a and first N-type layers 12b, which can improve the resistivity and stability of the composite substrate, thereby increasing the breakdown voltage of the composite substrate. When in the off state, the carriers in the first P-type layers 12a and the first N-type layers 12b of the superjunction structure are mutually depleted, reducing the number of free carriers in the composite substrate. Therefore, the device prepared from the composite substrate provided in the present disclosure can achieve high off-state breakdown voltage.

In some embodiments, the composite substrate further includes a SiC epitaxial layer 13, which is located on a side of the SiC monocrystalline layer 12 far from the support layer 11. The SiC epitaxial layer 13 has higher crystal quality than the SiC monocrystalline layer 12 to ensure the crystal quality of an epitaxial layer formed on the composite substrate and improve the stability of a device prepared from the composite substrate.

In some embodiments, the SiC epitaxial layer 13 includes a second superjunction structure that includes second P-type layers 13a and second N-type layers 13b, and the second P-type layers 13a and the second N-type layers 13b extend downward along a thickness direction of the SiC epitaxial layer 13 from a surface of the SiC epitaxial layer 13 far from the SiC monocrystalline layer 12, and are alternately distributed in a direction parallel to a plane of the SiC epitaxial layer 13.

The second P-type layers 13a and the second N-type layers 13b extend inward along the thickness direction of the SiC epitaxial layer 13 from the surface of the SiC epitaxial layer 13 far from the SiC monocrystalline layer 12, that is, the second P-type layers 13a and the second N-type layers 13b are both located within the SiC epitaxial layer 13 and thicknesses of the second P-type layers 13a and the second N-type layers 13b are less than or equal to the thickness of the SiC epitaxial layer 13. For example, the thickness of the second P-type layer 13a and the thickness of the second N-type layer 13b are both equal to the thickness of the SiC epitaxial layer 13, and for another example, the thickness of the second P-type layer 13a and the thickness of the second N-type layer 13b are both less than the thickness of the SiC epitaxial layer 13.

The second superjunction structure can further improve the resistivity and stability of the composite substrate.

FIG. 2 is a schematic structural diagram of a composite substrate according to embodiments of the present disclosure. As shown in FIG. 2, in some embodiments, along the thickness direction of the SiC monocrystalline layer 12, first P-type layers 12a and second P-type layers 13a are interconnected, and first N-type layers 12b and second N-type layers 13b are interconnected. A vertical device prepared from the composite substrate shown in FIG. 2 can effectively reduce the conduction resistance in the vertical direction.

FIG. 3 is a schematic structural diagram of a composite substrate according to embodiments of the present disclosure. As shown in FIG. 3, along the thickness direction of the SiC monocrystalline layer 12, first P-type layers 12a and second N-type layers 13b are interconnected, and first N-type layers 12b and second P-type layers 13a are interconnected.

The first P-type layers 12a are connected to the second N-type layers 13b, and the first N-type layers 12b are connected to the second P-type layers 13a, such that PN junctions can be formed in the vertical direction of the composite substrate (such as the thickness direction of the SiC monocrystalline layer 12), which can further improve the vertical resistivity of the composite substrate and improve the stability of the composite substrate.

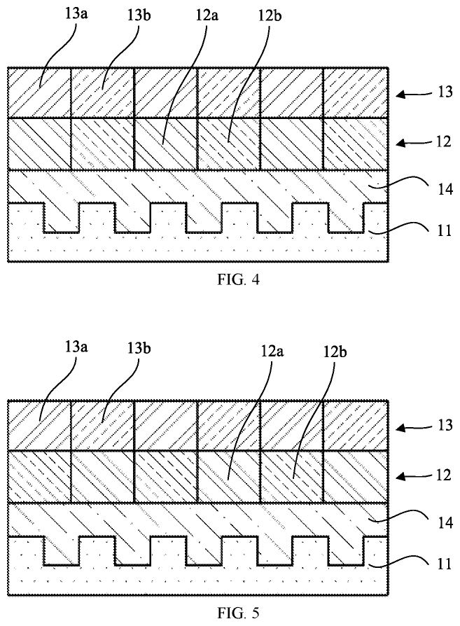

FIG. 4 is a schematic structural diagram of a composite substrate according to embodiments of the present disclosure. As shown in FIG. 4, in some embodiments, the composite substrate further includes a buried oxide layer 14 located between the support layer 11 and the SiC monocrystalline layer 12.

A material of the buried oxide layer can be SiO₂. The buried oxide layer can further improve the stability of the composite substrate.

As shown in FIGS. 4 and 5, in some embodiments, the support layer 11 includes multiple holes on the side close to the SiC monocrystalline layer 12, the holes partially penetrate the support layer 11, and the buried oxide layer 14 fills the holes and covers the surface of the support layer 11 near the SiC monocrystalline layer 12.

The holes on the support layer 11 can be achieved through etching, and the holes can increase the contact area and roughness of the contact surface between the support layer 11 and the buried oxide layer 14, making the connection between the support layer 11 and the buried oxide layer 14 stronger and the structure of the composite substrate more stable.

FIG. 6 is a top view of a support layer of a composite substrate according to embodiments of the present disclosure. As shown in FIG. 6, in some embodiments, the holes are arranged in an array arrangement.

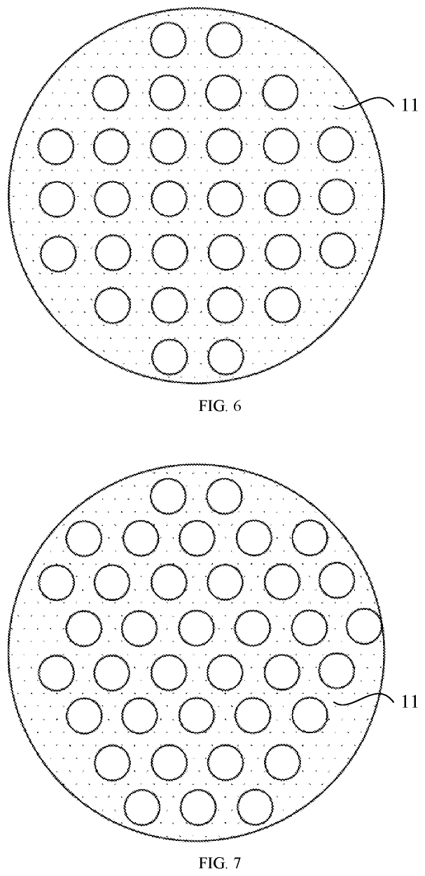

FIG. 7 is a top view of a support layer of a composite substrate according to embodiments of the present disclosure. As shown in FIG. 7, in some embodiments, the holes are arranged in a staggered arrangement.

Furthermore, in the present disclosure, a method for manufacturing a composite substrate is further provided, and includes: providing a support layer 11; forming a Si monocrystalline layer on the support layer 11; forming a first superjunction structure by implanting ions into the Si monocrystalline layer, where the first superjunction structure includes first P-type layers 12a and first N-type layers 12b, and the first P-type layers 12a and the first N-type layers 12b extend inward along a thickness direction of the Si monocrystalline layer from a surface of the Si monocrystalline layer far from the support layer 11, and are alternately distributed in a direction parallel to a plane of the Si monocrystalline layer; and after forming the first superjunction structure, obtaining a SiC monocrystalline layer 12 by carbonizing the Si monocrystalline layer.

A material of the support layer 11 can include a polycrystalline material, and in some embodiments, a material of the support layer 11 includes at least one of aluminum nitride ceramic substrate, aluminum oxide ceramic substrate, silicon carbide ceramic substrate, boron nitride ceramic substrate, zirconia ceramic substrate, magnesium oxide ceramic substrate, silicon nitride ceramic substrate, beryllium oxide ceramic substrate or polycrystalline silicon. The support layer 11 can provide stress compensation for the structure on the support layer 11, to prevent structural warping and improve structural stability.

Because lattice constants of SiC and GaN materials are similar, a GaN-based material grown on a SiC monocrystalline material have fewer defects and better properties. However, the cost of SiC monocrystalline materials is relatively high. In the embodiments, a Si monocrystalline material is carbonized to obtain the SiC monocrystalline layer, thereby effectively reducing costs. Since the thickness of the SiC monocrystalline layer is small, in the present disclosure, a first superjunction structure is further provided to enhance the resistivity and stability of the SiC monocrystalline layer. The first superjunction structure has multiple PN junctions composed of first P-type layers 12a and first N-type layers 12b, which can improve the resistivity and stability of the composite substrate.

Forming the first superjunction structure by implanting ions into the Si monocrystalline layer can include: implanting P-type ions onto the Si monocrystalline layer, and then implanting N-type ions onto the Si monocrystalline layer through a mask to form a superjunction structure with alternated P-type layers and N-type layers. In some embodiments, forming the first superjunction structure by implanting ions into the Si monocrystalline layer can include: implanting P-type ions onto the Si monocrystalline layer through a first mask, removing the first mask, and then implanting N-type ions onto the Si monocrystalline layer through a second mask to form a superjunction structure with alternated P-type layers and N-type layers.

In some embodiments, after obtaining the SiC monocrystalline layer 12 by carbonizing the Si monocrystalline layer, the method further includes: forming a SiC epitaxial layer 13 on a side of the SiC monocrystalline layer 12 far from the support layer 11.

The formation process of the SiC epitaxial layer 13 may include: atomic layer deposition (ALD), chemical vapor deposition (CVD), molecular beam epitaxy (MBE), plasma enhanced chemical vapor deposition (PECVD), low pressure chemical vapor deposition (LPCVD), metal-organic chemical vapor deposition (MOCVD), or a combination thereof.

The SiC epitaxial layer 13 has fewer defects, which is conducive to the growth of high-quality epitaxial structures.

In some embodiments, where after forming the SiC epitaxial layer 13 on the side of the SiC monocrystalline layer 12 far from the support layer 11, the method further includes: forming a second superjunction structure by implanting ions into the SiC epitaxial layer 13, where the second superjunction structure includes second P-type layers 13a and second N-type layers 13b, and the second P-type layers 13a and the second N-type layers 13b extend inward along a thickness direction of the SiC epitaxial layer 13 from a surface of the SiC epitaxial layer 13 far from the SiC monocrystalline layer 12, and are alternately distributed in a direction parallel to a plane of the SiC epitaxial layer 13.

The steps of ion implantation into the SiC epitaxial layer 13 to form a second superjunction structure are similar to the steps of forming the first superjunction structure, and are not repeated here.

In some embodiments, along the thickness direction of the SiC monocrystalline layer 12, first P-type layers 12a and second P-type layers 13a are interconnected, and first N-type layers 12b and second N-type layers 13b are interconnected.

In some embodiments, along the thickness direction of the SiC monocrystalline layer 12, first P-type layers 12a and second N-type layers 13b are interconnected, and first N-type layers 12b and second P-type layers 13a are interconnected.

The first P-type layers 12a are connected to the second N-type layers 13b, and the first N-type layers 12b are connected to the second P-type layers 13a, such that PN junctions can be formed in the vertical direction of the composite substrate, which can further improve the vertical resistivity of the composite substrate and improve the stability of the composite substrate.

In some embodiments, forming the Si monocrystalline layer on the support layer 11 includes: forming a buried oxide layer 14 on the support layer 11; forming the Si monocrystalline layer on a side of the buried oxide layer 14 far from the support layer 11.

The formation process of the buried oxide layer 14 is similar to the formation process of the SiC epitaxial layer 13, and is not elaborated here.

In some embodiments, forming the buried oxide layer 14 on the support layer 11 further includes: forming holes on the support layer 11, where the holes partially penetrate the support layer 11; and forming the buried oxide layer 14 on the support layer 11, where the buried oxide layer fills the holes and covers a surface of the support layer 11 on which the holes are located.

The holes on the support layer 11 can be achieved through etching, and the holes can increase the contact area and roughness between the support layer 11 and the buried oxide layer 14, making the connection between the support layer 11 and the buried oxide layer 14 stronger and the structure of the composite substrate more stable.

In some embodiments, as shown in FIGS. 6 and 7, the holes are arranged in an array arrangement or a staggered arrangement.

Further, in the present disclosure, a semiconductor structure is further provided, and includes a composite substrate according to any one of the above embodiments, where the semiconductor structure further includes one of a high-electron-mobility transistor device, a vertical power device, a radio frequency device and a light-emitting diode device.

The present disclosure adopts a scheme that combines a support layer and a SiC monocrystalline layer, which can effectively reduce the thickness of the SiC monocrystalline layer and thereby reduce costs. In addition, in the present disclosure, a first superjunction structure is further provided to enhance the resistivity and stability of the SiC monocrystalline layer. The first superjunction structure has multiple PN junctions composed of first P-type layers and first N-type layers, which can improve the resistivity and stability of the composite substrate, thereby increasing the breakdown voltage of the composite substrate. When in the off state, the carriers in the first P-type layers and the first N-type layers of the superjunction structure are mutually depleted, reducing the number of free carriers in the composite substrate. Therefore, the device prepared from the composite substrate provided in the present disclosure can achieve high off-state breakdown voltage.

It should be noted that, while this specification contains many specific embodiments, these embodiments should not be understood as limiting the scope of any invention or what may be claimed, but are used to describe features of specific embodiments of particular inventions. Certain features described in a single embodiment in this specification may also be implemented in combination in other embodiments. On the other hand, the various features described in various embodiments can also be implemented in any suitable combination. Furthermore, although features may function as described above in certain combinations and even be originally claimed as such, one or more features from a claimed combination may in some cases be removed from the combination and the claimed protected combination may point to a subcombination or a variation of a subcombination.

Therefore, specific embodiments of the present disclosure have been described. Other embodiments are within the scope of the appended claims. In some cases, the features recited in the claims can be performed in a different order and still achieve the desirable result. In addition, the order of the features depicted in the accompanying drawings is not necessary in a particular order or sequential order to achieve the desirable results. In some implementations, it may also be multitasking and parallel processing.

The foregoing are only some embodiments of the present disclosure and are not intended to limit the present disclosure, and any modifications, equivalent substitutions, improvements, etc., made within the spirit and principles of the present disclosure shall be included within the scope of protection of the present disclosure.

What is claimed is:

1. A composite substrate, comprising:
a support layer; and
a SiC monocrystalline layer on the support layer, wherein the SiC monocrystalline layer comprises a first superjunction structure that comprises first P-type layers and first N-type layers, and the first P-type layers and the first N-type layers extend inward along a thickness direction of the SiC monocrystalline layer from a surface of the SiC monocrystalline layer far from the support layer, and are alternately distributed in a direction parallel to a plane of the SiC monocrystalline layer.

2. The composite substrate according to claim 1, further comprising:
a SiC epitaxial layer on a side of the SiC monocrystalline layer far from the support layer.

3. The composite substrate according to claim 2, wherein
the SiC epitaxial layer comprises a second superjunction structure that comprises second P-type layers and second N-type layers, and the second P-type layers and the second N-type layers extend inward along a thickness direction of the SiC epitaxial layer from a surface of the SiC epitaxial layer far from the SiC monocrystalline layer, and are alternately distributed in a direction parallel to a plane of the SiC epitaxial layer.

4. The composite substrate according to claim 3, wherein
along the thickness direction of the SiC monocrystalline layer, the first P-type layers are connected to the second P-type layers, and the first N-type layers are connected to the second N-type layers.

5. The composite substrate according to claim 3, wherein
along the thickness direction of the SiC monocrystalline layer, the first P-type layers are connected to the second N-type layers, and the first N-type layers are connected to the second P-type layers.

6. The composite substrate according to claim 1, further comprising:
a buried oxide layer between the support layer and the SiC monocrystalline layer.

7. The composite substrate according to claim 6, wherein
the support layer comprises holes on a side close to the SiC monocrystalline layer, the holes partially penetrate the support layer, and the buried oxide layer fills the holes and covers a surface of the support layer close to the SiC monocrystalline layer.

8. The composite substrate according to claim 7, wherein
the holes are arranged in an array arrangement or a staggered arrangement.

9. The composite substrate according to claim 1, wherein
a material of the support layer comprises a polycrystalline material, and a material of the support layer comprises at least one of aluminum nitride ceramic substrate, aluminum oxide ceramic substrate, silicon carbide ceramic substrate, boron nitride ceramic substrate, zirconia ceramic substrate, magnesium oxide ceramic substrate, silicon nitride ceramic substrate, beryllium oxide ceramic substrate or polycrystalline silicon.

10. A method for manufacturing a composite substrate, comprising:
providing a support layer;
forming a Si monocrystalline layer on the support layer;
forming a first superjunction structure by implanting ions into the Si monocrystalline layer, wherein the first superjunction structure comprises first P-type layers and first N-type layers, and the first P-type layers and the first N-type layers extend inward along a thickness direction of the Si monocrystalline layer from a surface of the Si monocrystalline layer far from the support layer, and are alternately distributed in a direction parallel to a plane of the Si monocrystalline layer; and
after forming the first superjunction structure, obtaining a SiC monocrystalline layer by carbonizing the Si monocrystalline layer.

11. The method according to claim 10, wherein after obtaining the SiC monocrystalline layer, the method further comprises:
forming a SiC epitaxial layer on a side of the SiC monocrystalline layer far from the support layer.

12. The method according to claim 11, wherein after forming the SiC epitaxial layer on the side of the SiC monocrystalline layer far from the support layer, the method further comprises:
forming a second superjunction structure by implanting ions into the SiC epitaxial layer, wherein the second superjunction structure comprises second P-type layers and second N-type layers, and the second P-type layers and the second N-type layers extend inward along a thickness direction of the SiC epitaxial layer from a surface of the SiC epitaxial layer far from the SiC monocrystalline layer, and are alternately distributed in a direction parallel to a plane of the SiC epitaxial layer.

13. The method according to claim 12, wherein
along the thickness direction of the SiC monocrystalline layer, the first P-type layers are connected to the second P-type layers, and the first N-type layers are connected to the second N-type layers.

14. The method according to claim 12, wherein
along the thickness direction of the SiC monocrystalline layer, the first P-type layers are connected to the second N-type layers, and the first N-type layers are connected to the second P-type layers.

15. The method according to claim 10, wherein forming the Si monocrystalline layer on the support layer comprises:
forming a buried oxide layer on the support layer; and
forming the Si monocrystalline layer on a side of the buried oxide layer far from the support layer.

16. The method according to claim 15, wherein forming the buried oxide layer on the support layer comprises:
forming holes on the support layer, wherein the holes partially penetrate the support layer; and
forming the buried oxide layer on the support layer, wherein the buried oxide layer fills the holes and covers a surface of the support layer on which the holes are located.

17. The method according to claim 16, wherein
the holes are arranged in an array arrangement or a staggered arrangement.

18. A semiconductor structure, comprising the composite substrate according to claim 1, and one of a high-electron-mobility transistor device, a vertical power device, a radio frequency device and a light-emitting diode device.
